(19) United States
(12) Patent Application Publication
(10) Pub. No.: US 2006/0044164 A1
(43) Pub. Date: Mar. 2, 2006

(54) Reproduction system, reproduction equipment and reproduction method

(75) Inventors: Kenji Takahashi, Osaka (JP); Makoto Takano, Otsu-shi (JP)

Correspondence Address: BACON & THOMAS, PLLC, 625 SLATERS LANE, FOURTH FLOOR, ALEXANDRIA, VA, 22314, US

(73) Assignee: Matsushita Electric Industrial Co., Ltd., Osaka (JP)

(21) Appl. No.: 11/200,118

(22) Filed: Aug. 10, 2005

(30) Foreign Application Priority Data
Sep. 2, 2004 (JP) 2004-255208

(51) Int. Cl. H03M 7/00

(52) U.S. Cl. 341/50

(57) ABSTRACT

A reproduction system is capable of networking a plurality of reproduction equipments via a communications network. Each equipment is capable of reproducing a data signal and comprises a manipulation unit for receiving an input operation, a reproduction unit for reproducing a program by using a recording medium, an operation unit for processing various information and for sorting out data recorded on the recording medium, and a network interface unit which allows for referring to program data stored in a recording medium of a reproduction unit of another reproduction equipment via communication. In particular, when a reproduction equipment receives an inquiry for a rank of a particular program after performing a sorting operation on program data stored therein from another reproduction equipment networked therewith, the former reproduction equipment responds thereto by notifying the latter reproduction equipment of the program's rank.

### FIELD OF THE INVENTION

The present invention relates to a plurality of reproduction equipments that are networked via a communications network and a reproduction method therefor.

### BACKGROUND OF THE INVENTION

A reproduction equipment, such as DVD recorder, hard disk recorder or the like, has the function of reading program (e.g., movie or music files) data stored on a hard disk drive (HDD), DVD drive or the like embedded therein, and displaying a list of program data on the screen. However, as the number of programs increases, it becomes difficult to search for a desired program. Therefore, the reproduction unit normally includes a sorting function which allows a user to search programs easily by rearranging programs in accordance with title, start time etc. In general, if a particular program has been selected before sorting, hence a program has already been focused, the selected program will remain selected after sorting just as before sorting.

As for reproduction equipments that are linked to each other via a communications network such as LAN or the like, to display program data stored in another reproduction equipment, the program data is exchanged in the manner of the method disclosed in patent document 1. Among a plurality of reproduction equipments, a server is defined as the reproduction equipment which is storing programs or their data to be reproduced, and which transmits the data to another reproduction equipment; whereas a client, as the reproduction equipment which receives the programs or their program data from the server. When a client is to display a list of server's program data, the server needs to transmit its program data to the client.

When manipulating the client to sort the program data of the server, there can be two ways: sorting on the server and sorting on the client. And sorting on the server is more commonly done.

When sorting is done on the server, to maintain focusing on a particular program both before and after sorting as described previously, the client needs to know the rank of the program to be refocused after the sorting. Even when sorting is done on the server, the client can identify the rank of the program to be focused on if the client still receives all the program data via a communications network. However, the overall process will take time due to increase in the volume of traffic on the communications network.

Further, there can be a case wherein the programs stored in the server is individually identified by unique numbers; and a particular number can be entered by the number key pad of a remote control or the like of the client to display a listing of program data including a selected program and others before and after thereof. In this case, even if the program identification numbers become shuffled after sorting, the client still needs to know the rank of the program which is identified by the entered number within the newly sorted listing. Similarly, if the client were to receive all the program data, the client can identify the rank of the program to be focused on. However, the overall process will still take time due to increase in the volume of traffic on the communications network.

[Patent document 1] Japanese Patent Laid-open Application No. 2002-304333.

### SUMMARY OF THE INVENTION

The following are problems to be solved by the present invention. First, when one reproduction equipment remotely attempts to sort out program data stored in another reproduction equipment linked therewith via a communications network, it would take time to complete the overall process. This is true if the same program were to remain focused before and after the sorting, since the volume of traffic on the communications network necessary to determine which particular programs are to be displayed would be increased. Secondly, the problem arises in the context of having an individualized identification number assigned to each of the programs stored in another reproduction equipment. An example is the case when a remote reproduction equipment (client) enters an identification number to display a listing of programs including the selected number. Here, it will take time to prepare such a listing due to increase in the volume of traffic on the network.

Therefore, the primary objective of the present invention is to provide a reproduction system, a reproduction equipment and a reproduction method, whereby only a low traffic volume on the network would be necessary when a client reproduction equipment remotely attempts to sort out program data of a server reproduction equipment. This is accomplished while maintaining focusing on a particular program before and after the sorting.

Another objective of the present invention is to provide a reproduction system, a reproduction equipment and a reproduction method, whereby only a low traffic volume through the network would be necessary when a client reproduction equipment enters a number identifying a particular program. Hence a sorted listing of program data stored in a remote server reproduction equipment linked via a communications network can be prepared including the selected program.

The present invention offers advantages in the following settings. First, when one reproduction equipment remotely attempts to sort out program data stored in another reproduction equipment linked therewith via a communications network. This is especially true if the same program were to remain focused before and after the sorting. Secondly, when an individualized identification number is assigned to each of the programs stored in another reproduction equipment. This is the case especially if the numbers are shuffled by sorting or the like (i.e., in random order). Overall, in these situations, the processes of listing programs can be achieved at a low traffic level through the network.

In accordance with one aspect of the of the present invention, there is provided a reproduction system capable of networking a plurality of reproduction equipments via a communications network, each equipment being capable of reproducing a data signal and comprising: a manipulation unit for receiving an input operation; a reproduction unit for reproducing a program by using a recording medium; an operation unit for processing various information and for sorting out data recorded on the recording medium; and a network interface unit which allows for referring to program data stored in a recording medium of a reproduction unit of another reproduction equipment via communication, wherein when a reproduction equipment receives an inquiry for a rank of a particular program after performing a sorting operation on program data stored therein from another reproduction equipment networked therewith, the former reproduction equipment responds thereto by notifying the latter reproduction equipment of the program's rank.

In accordance with another aspect of the present invention, there is provided a reproduction equipment comprising: a manipulation unit for receiving an input operation to the reproduction equipment; a reproduction unit for reproducing a program by using a recording medium; an operating unit for processing various information and for sorting out data recorded on the recording media; and a network interface unit which allows another reproduction equipment to refer to program data stored in the recording medium of the reproduction unit via communication, wherein the reproduction equipment and said another reproduction equipment are interconnected by a communications network; and when the reproduction equipment receives an inquiry for a rank of a particular program after performing a sorting operation on program data stored therein from said another reproduction equipment networked therewith, the reproduction equipment responds thereto by notifying said another reproduction equipment of the program's rank.

In accordance with still another aspect of the present invention, there is provided a reproduction method using a reproduction system capable of networking a plurality of reproduction equipments via a communications network, each equipment being capable of reproducing a data signal, the reproduction method comprising the steps of: by one of the reproduction equipments, receiving an inquiry from another reproduction equipment for a rank of a specific program when a sorting operation is performed therein; and responding hereto by notifying said reproduction equipment of the rank.

As a result, when a reproduction equipment, which is linked to other reproduction equipments via a communications network such as LAN or the like, sorts out program data, namely on a server reproduction equipment, in case the same program should remain focused or in case each program stored in a remote reproduction equipment is identified by a unique number, or even in case such numbers are arranged in random order, by entering such a number a program data listing including the number would be provided with a low traffic volume on the network in a short time.

In accordance with still another aspect of the present invention, there is provided a reproduction system capable of networking a plurality of reproduction equipments via a communications network, each equipment being capable of reproducing a data signal and comprising: a manipulation unit for receiving an input operation to be applied; a reproduction unit for reproducing a program by using a recording medium; an operation unit for processing various information; and a network interface unit which allows for referring to program data stored in a recording medium of a reproduction unit of another reproduction equipment via communication, wherein a reproduction equipment receives an inquiry for a rank of a program having a unique identification number from another reproduction equipment networked therewith, the former reproduction equipment responds thereto by notifying the latter reproduction equipment of the program's rank.

In accordance with still another aspect of the present invention, there is provided a reproduction equipment comprising: a manipulation unit for receiving an input operation to the reproduction equipment; a reproduction unit for reproducing a program by using a recording medium; an operating unit for processing various information; and a network interface unit which allows another reproduction equipment to refer to program data stored in the recording medium of the reproduction unit via communication, wherein the reproduction equipment and said another reproduction equipment are interconnected by a communications network; and when the reproduction equipment receives an inquiry for a rank of a program having a unique identification number from said another reproduction equipment networked therewith, the reproduction equipment responds thereto by notifying said another reproduction equipment of the program's rank.

In accordance with still another aspect of the present invention, there is provided a reproduction method using a reproduction system capable of networking a plurality of reproduction equipments via a communications network, each equipment being capable of reproducing a data signal, the reproduction method comprising the steps of: by one of the reproduction equipments, receiving an inquiry from another reproduction equipment for a rank of a program having a unique identification number; responding thereto by notifying said another reproduction equipment of the rank.

As a result, in a reproduction equipment linked with other reproduction equipments linked therewith via LAN or the like, wherein program data stored in another reproduction equipment are individually identified by numbers, even if the numbers becomes arranged in random order after sorting, a program listing can be provided by selecting a program number so that the listing would include the selected number. Overall, this process will only require a low traffic volume on the network.

### BRIEF DESCRIPTION OF THE DRAWINGS

The above and other objects and features of the present invention will become apparent from the following description of preferred embodiments given in conjunction with the accompanying drawings, in which:

FIG. 1 is a block diagram showing a system configuration of a reproduction system in accordance with the first and the second embodiments of the present invention;

FIG. 2 is a flow chart explaining the operations of reproduction equipments 1 and 2 in accordance with the first embodiment of the present invention; and

FIG. 3 is a flow chart explaining the operations of reproduction equipments 1 and 2 in accordance with the second embodiment of the present invention.

### DETAILED DESCRIPTION OF THE PREFERRED EMBODIMENTS

Hereinafter, preferred embodiments of the present invention will be described with reference to the accompanying drawings. It should be noted that the preferred embodiments are only for illustration purpose and the scope of the present invention is not limited thereto.

### Embodiment 1

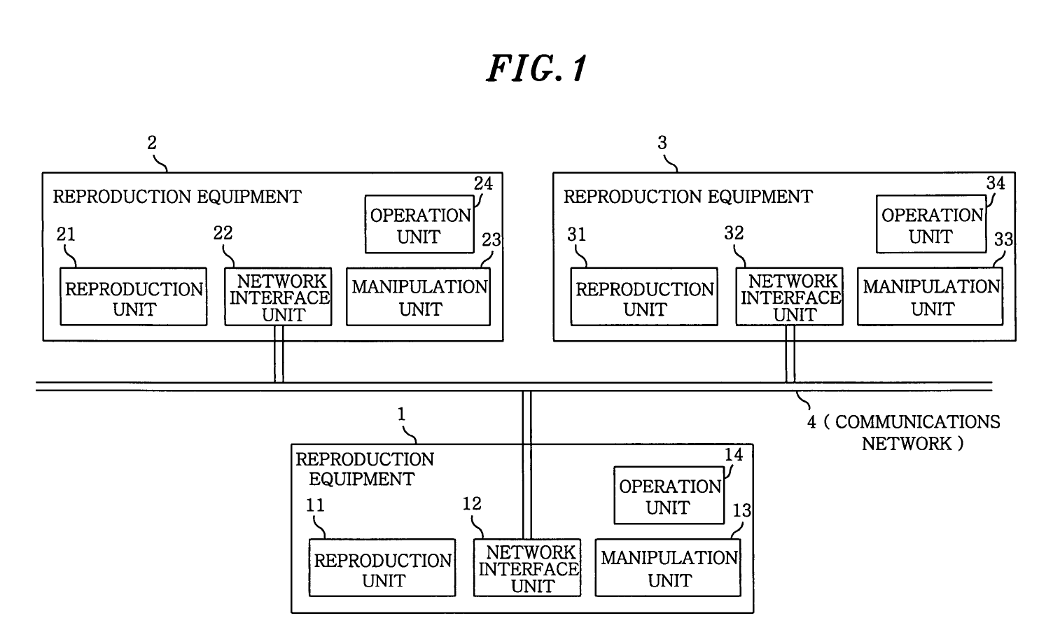

FIG. 1 is a block diagram of a reproduction system in accordance with a preferred embodiment 1. In FIG. 1, reference numerals 1 to 3 are for reproduction equipments and reference numeral 4 indicates a communications network. In addition, reference numerals 11, 21, 31 are for reproduction units, reference numerals 12, 22, 32 represent network interface units, reference numerals 13, 23, 33 are for manipulation units, and reference numerals 14, 24, 34 are for operation units.

Although FIG. 1 is an example of the reproduction system having three reproduction equipments, it is acceptable so long as the reproduction system has at least two reproduction equipments.

Communications network 4 provides a means to exchange program data that are stored in recording media of reproduction units of reproduction equipments, and such means include Ethernet (registered trademark), wireless LAN or the like. Such a communications network may have a configuration which includes a router or hub.

Reproduction units 11, 21, 31, which provide a reproduction function, are capable of reading from recording media, i.e. hard disk drive, recordable disk such as DVD-RAM, memory card etc., and they can not only receive program data but also reproduce the program. In addition, examples of such a reproduction unit are not limited to the above examples; so long as a reproduction unit is capable of recording, it would be acceptable.

Network interface units 12, 22, 32 provide a communication function with other reproduction equipments and specific examples include terminals of Ethernet (registered trademark). Further, since Ethernet (registered trademark) is used as communications units 4 in the present embodiment, the network interface unit is referred as Ethernet terminal. But needless to say, the terminal selection depends on the communications method used.

Manipulation units 13, 23, 33 allow a user to command various operations on each reproduction equipment. For example, manipulation units may be a remote control as part of a reproduction equipment or main control buttons provided in each reproduction equipment.

Operation units 14, 24, 34 provide a data processing function as each reproduction unit communicates with reproduction units, network interface units or manipulation units. In addition, operation units can process or rearrange (sort) data that are recorded on the recording media. Further, in FIG. 1, although connection lines which link up each block within each reproduction equipment are omitted for simplicity of explanation, in reality, each of the blocks are linked with others so that they can exchange data or signals.

With respect to the operation of the reproduction equipment configured as described above in the first embodiment, hereinafter, it is explained with reference to the figures provided when the reproduction equipments 1 and 2 are connected as an example.

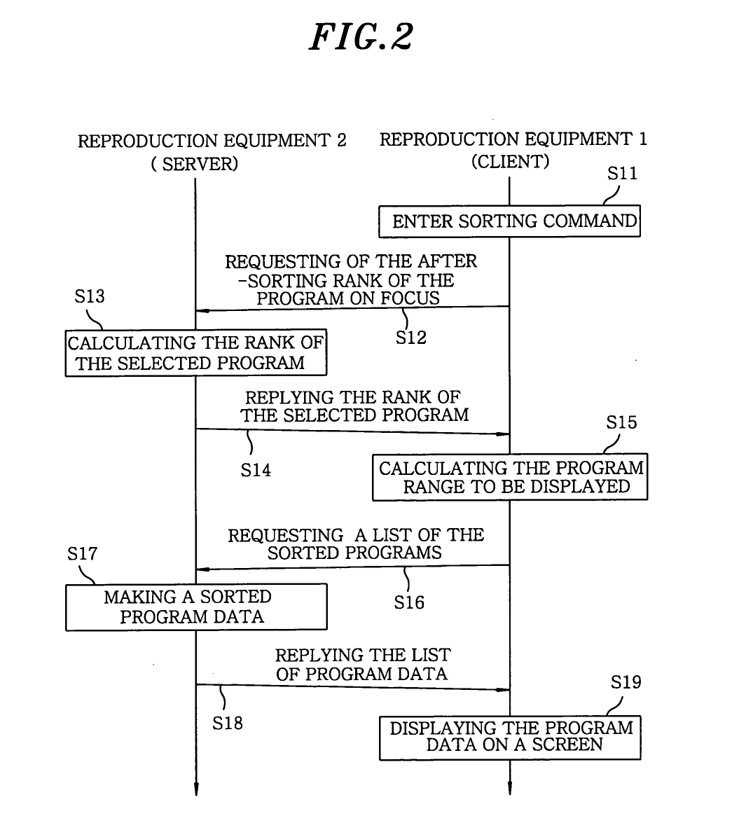

In FIG. 2, reproduction equipment 1 works as client and reproduction equipment 2 as server.

In S11, a user executes a sorting (rearrangement) command by using buttons provided in e.g., a remote control or the like, with respect to a list of programs stored in the server and displayed on a television screen (not shown) or the likes which is connected to reproduction equipment 1. For example, such an operation by remote control buttons or the like can include switching a focused program or executing a sorting based on a new criteria designated.

In S12, to identify the after-sorting rank of a program which was previously on focus (the condition wherein the cursor is highlighting a particular program on the program list), the data (title, date, status w/o sorting etc.) that can identify the program on focus, is transmitted from reproduction equipment 1 to reproduction equipment 2 so that they can be searched.

In S13, after the reproduction equipment 2 sorts out programs in accordance with the sorting criteria selected by reproduction equipment 1, the reproduction equipment 2 calculates the rank of the selected program.

In S14, reproduction equipment 2 transmits the rank data calculated in S13 to reproduction equipment 1.

In S15, based on the rank data from S14, reproduction equipment 1 calculates the range of programs to be included, therefore displayed.

In S16, reproduction equipment 1 transmits the program range data to be displayed to reproduction equipment 2 and requests a sorted list of programs as a response. At this time, reproduction equipment 1 may also send the sorting criteria therewith to the reproduction equipment 2 in order to reconfirm on what basis the sorted program data is prepared. As for the data to represent the range of programs to be displayed, it can be in the format of providing the start and end points in the list; providing only the start point and the number of programs to be included; or otherwise, simply in the format of program ranks.

In S17, reproduction equipment 2 then prepares a sorted program data list in accordance with the sorting criteria designated by reproduction equipment 1 and within the range based on the program data in S16.

In S18, reproduction equipment 2 transmits the program data list prepared in S17 to reproduction equipment 1.

In S19, reproduction equipment 1 displays the program data on the screen based on the program data received from S18.

In addition, the steps of S16 through S18 or S19 can be executed at once or otherwise, carried out in several groups.

Following these progressive steps, when sorting is done for program data that are stored on the reproduction equipment, which is linked by a communications network such as LAN and the like, in case sorting is done on a server reproduction equipment such that a same program remains focused both before and after sorting, the overall process is completed quickly due to only a low level of data transmission requirement.

### Embodiment 2

FIG. 1 is a block diagram of a reproduction system in accordance with the second embodiment. Since FIG. 1 has already been discussed, its explanation will be omitted here.

Next, the operations of reproduction equipments 1 and 2 in accordance with the second embodiment of the present invention are explained with reference to the figures provided.

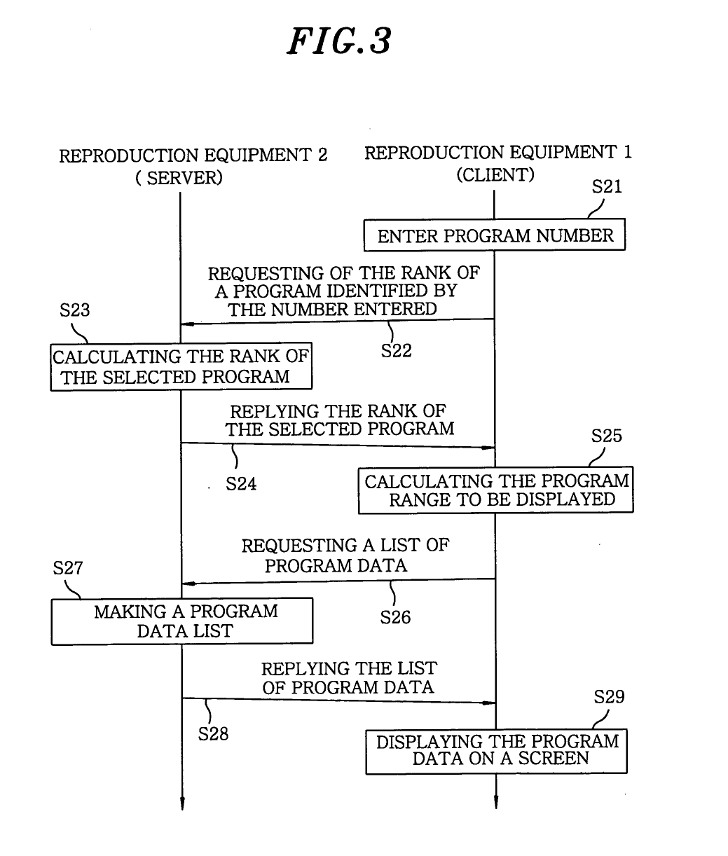

In FIG. 3, reproduction equipment 1 works as client and reproduction equipment 2 as server.

In S21, a user can enter a number with remote control buttons or the like with respect to a list of programs being displayed on a television screen or the likes connected to the reproduction equipment 1. The number can be entered, for example, using a number key pad with buttons from 0 to 9 (ten keys). Further, a user can also executes a sorting (rearrange) command using the remote control buttons or the like with respect to the list of programs in the server.

In S22, to identify the rank of a program identified by the number entered, from reproduction equipment 1 to reproduction equipment 2, the following data is transmitted: program data identified by the program number, requested sorting criteria (e.g., title, start time, status w/o sorting etc.) and so on.

In S23, after the reproduction equipment 2 sorts out programs in accordance with the sorting criteria selected by reproduction equipment 1, reproduction equipment 2 then calculates the rank of the selected program.

In S24, reproduction equipment 2 then sends the rank data calculated in S23 to reproduction equipment 1.

In S25, based on the rank data received in S24, reproduction equipment 1 calculates the range of programs to be displayed, including the selected program.

In S26, reproduction equipment 1 requests reproduction equipment 2 as to a list of program data by sending the program range data to be displayed. At this time, reproduction equipment 1 can also send the sorting criteria therewith to reproduction equipment 2 in order to reconfirm on what basis the sorted program data is prepared. As for the data to represent the range of programs to be displayed, it can be in the format of providing the start and end points in the list; providing only the start point and the number of programs to be included; or otherwise, simply in the format of program ranks.

In S27, reproduction equipment 2 then prepares a sorted program data list in accordance with the sorting criteria designated by reproduction equipment 1 and within the range based on the program data in S26.

In S28, reproduction equipment 2 then sends the sorted program list prepared in S27 to reproduction equipment 1.

In S29, reproduction equipment I displays the program data on the screen based on the program data list received in S28.

In addition, the steps of S26 through S28 or S29 can be executed at once or otherwise, carried out in several groups.

Following these progressive steps, when programs stored in a different reproduction equipment are individually identified by unique numbers, even if these numbers become shuffled after rearrangement such as by sorting, by entering a number which represent the ID of a particular program, a sorted list of programs including the selected program can be obtained quickly due to only a low level of data transmission requirement.

A reproduction equipment in accordance with the present inventions includes a manipulation unit for receiving an operation to be applied, a reproduction unit for reproducing a program by using a recording medium, an operation unit for processing various data and sorting out data recorded on the recording medium, and a network connecting unit for retrieval of program data stored in the recording medium of the reproduction unit of another reproduction equipment via communication, wherein when one of the reproduction equipments received a sorting operation to be performed therein from another of the reproduction equipments networked therewith, the sorting operation is followed by an inquiry of a particular program's rank which is returned to the another of the reproduction equipments.

These features can be applied to reproduction equipments that are linked by a communications network such as LAN. The applicable situations include when sorting of programs is done on a server reproduction equipment while keeping the same program on focus, or otherwise when the programs are individually identified by unique numbers that will be shuffled after sorting. In the latter situation, the selected program is identified by a number entered by a user and the sorted list will be prepared to include the program of the number entered. Overall, these features allow a desired sorting to be done rather quickly at a low data transmission level.

While the invention has shown and described with respect to the preferred embodiments, it will be understood by those skilled in the art that various changes and modifications may be made without departing from the spirit and scope of the invention as defined in the following claims.

What is claimed is:

1. A reproduction system capable of networking a plurality of reproduction equipments via a communications network, each equipment being capable of reproducing a data signal and comprising:
a manipulation unit for receiving an input operation;
a reproduction unit for reproducing a program by using a recording medium;
an operation unit for processing various information and for sorting out data recorded on the recording medium; and
a network interface unit which allows for referring to program data stored in a recording medium of a reproduction unit of another reproduction equipment via communication,
wherein when a reproduction equipment receives an inquiry for a rank of a particular program after performing a sorting operation on program data stored therein from another reproduction equipment networked therewith, the former reproduction equipment responds thereto by notifying the latter reproduction equipment of the program's rank.

2. A reproduction equipment comprising:
a manipulation unit for receiving an input operation to the reproduction equipment;
a reproduction unit for reproducing a program by using a recording medium;
an operating unit for processing various information and for sorting out data recorded on the recording media; and
a network interface unit which allows another reproduction equipment to refer to program data stored in the recording medium of the reproduction unit via communication,
wherein the reproduction equipment and said another reproduction equipment are interconnected by a communications network; and when the reproduction equipment receives an inquiry for a rank of a particular program after performing a sorting operation on program data stored therein from said another reproduction equipment networked therewith, the reproduction equipment responds thereto by notifying said another reproduction equipment of the program's rank.

3. A reproduction method using a reproduction system capable of networking a plurality of reproduction equipments via a communications network, each equipment being capable of reproducing a data signal, the reproduction method comprising the steps of:
by one of the reproduction equipments, receiving an inquiry from another reproduction equipment for a rank of a specific program when a sorting operation is performed therein; and
responding thereto by notifying said reproduction equipment of the rank.

4. A reproduction system capable of networking a plurality of reproduction equipments via a communications network, each equipment being capable of reproducing a data signal and comprising:
a manipulation unit for receiving an input operation to be applied;
a reproduction unit for reproducing a program by using a recording medium;
an operation unit for processing various information; and
a network interface unit which allows for referring to program data stored in a recording medium of a reproduction unit of another reproduction equipment via communication,
wherein a reproduction equipment receives an inquiry for a rank of a program having a unique identification number from another reproduction equipment networked therewith, the former reproduction equipment responds thereto by notifying the latter reproduction equipment of the program's rank.

5. A reproduction equipment comprising:
a manipulation unit for receiving an input operation to the reproduction equipment;
a reproduction unit for reproducing a program by using a recording medium;
an operating unit for processing various information; and
a network interface unit which allows another reproduction equipment to refer to program data stored in the recording medium of the reproduction unit via communication,
wherein the reproduction equipment and said another reproduction equipment are interconnected by a communications network; and when the reproduction equipment receives an inquiry for a rank of a program having a unique identification number from said another reproduction equipment networked therewith, the reproduction equipment responds thereto by notifying said another reproduction equipment of the program's rank.

6. A reproduction method using a reproduction system capable of networking a plurality of reproduction equipments via a communications network, each equipment being capable of reproducing a data signal, the reproduction method comprising the steps of:
by one of the reproduction equipments, receiving an inquiry from another reproduction equipment for a rank of a program having a unique identification number;
responding thereto by notifying said another reproduction equipment of the rank.
